(19) United States
(12) Patent Application Publication
(10) Pub. No.: US 2015/0280049 A1
(43) Pub. Date: Oct. 1, 2015

(54) Multi-junction Thin-Film Silicon Solar Cells with a Recrystallized Silicon-based Sub-Cell

(71) Applicant: TEL Solar AG, Trubbach (CH)

(72) Inventors: Evelyne Vallat-Sauvain, Chezard-St. Martin (CH); Johannes Meier, Corcelles (CH)

(73) Assignee: TEL Solar AG, Trubbach (CH)

(21) Appl. No.: 14/224,243

(22) Filed: Mar. 25, 2014

(51) Int. Cl. H01L 31/18; H01L 31/20

(52) U.S. Cl. CPC H01L 31/1864; H01L 31/1824; H01L 31/1884; H01L 31/1872; H01L 31/202

(57) ABSTRACT

This application relates to systems and methods for multi-junction solar cells that includes at least one recrystallized silicon layer. The recrystallized silicon lay may have a microcrystalline structure following a heat treatment or laser treatment of an amorphous silicon layer. The multi-junction solar cell may be a p-i-n or n-i-p structure that may include a p-type doped silicon layer, an intrinsic silicon layer, and an n-doped silicon layer. In one embodiment, the intrinsic layer in either type of structure may be the recrystallized silicon layer.

### BACKGROUND OF THE INVENTION

The disclosed embodiment relates generally to a method and apparatus for manufacturing a photovoltaic device, more particularly to using methods for recrystallizing silicon layer in the photovoltaic device.

Silicon deposition, among other processed, may be used to manufacture photovoltaic devices that convert solar radiation into electrical energy. Silicon layers, within the photovoltaic device, may be arranged to implement the energy conversion process. The silicon-based layers may be varied based on thickness, dopant concentration, and a degree of crystallinity to control the energy conversion process. Photovoltaic device manufacturing cost may be impacted by the degree of crystallinity. In that, higher crystalline silicon (e.g., microcrystalline silicon) is more expensive to deposit than lower crystalline silicon (e.g., amorphous silicon). Accordingly, there is a desire for new and improved methods and apparatuses that enable the use of amorphous silicon over the use of microcrystalline silicon.

### BRIEF DESCRIPTION OF THE DRAWINGS

The features within the drawings are numbered and are cross-referenced with the written description. Generally, the first numeral reflects the drawing number where the feature was first introduced, and the remaining numerals are intended to distinguish the feature from the other notated features within that drawing. However, if a feature is used across several drawings, the number used to identify the feature in the drawing where the feature first appeared will be used. Reference will now be made to the accompanying drawings, which are not necessarily drawn to scale and wherein:

FIG. 1 illustrates a simplified diagram of a multi-junction p-i-n solar cell comprising a recrystallized silicon layer in the top solar cell as described in one or more embodiments of the disclosure.

FIG. 2 illustrates a simplified diagram of a multi-junction n-i-p solar cell comprising a recrystallized silicon layer in a lower solar cell as described in one or more embodiments of the disclosure.

FIG. 3 illustrates a simplified diagram of a triple p-i-n solar cell comprising a recrystallized silicon layer in the top solar cell as described in one or more embodiments of the disclosure.

FIGS. 4 & 5 illustrate a method flow diagram for generating a multi-junction p-i-n solar cell as described in one or more embodiments of the disclosure.

FIGS. 6 & 7 illustrate a method flow diagram for generating a multi-junction p-i-n solar cell as described in one or more embodiments of the disclosure.

### DETAILED DESCRIPTION

Techniques disclosed herein include methods and apparatus for multi-junction solar cells that may include recrystallized silicon layers. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the concepts described in this application can be embodied and viewed in many different ways.

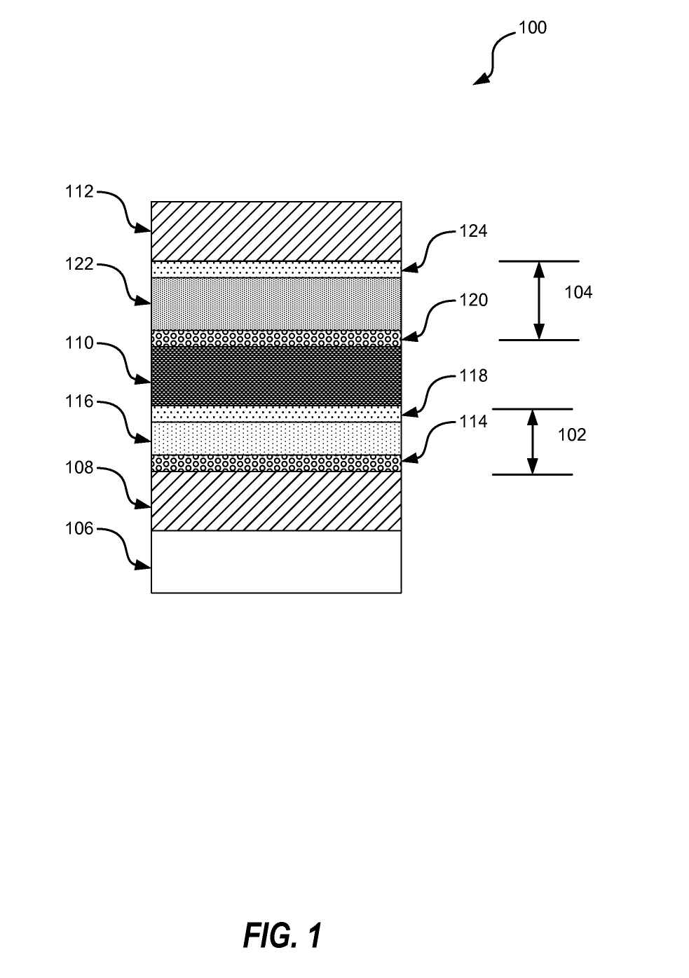

FIG. 1 illustrates a simplified diagram of a multi-junction p-i-n solar cell device 100 that may be used to convert solar radiation to electricity. Generally, solar cells may include several silicon layers that operate in concert with each other to induce electron flow within the silicon layers. For example, the solar radiation that passes through the solar cell device 100 may include photons that excite electrons in the silicon layers to a higher state of energy that allows the electrons to act as charge carriers for an electric current. By varying characteristics of the silicon layers, the solar cell device 100 efficiency may be improved. The characteristics may include, but are not limited to, thickness, dopant concentration, Hydrogen content and degree of crystallinity.

The thickness of the solar cell layers may be the distance between the interfaces of each layer. For example, thickness may be measured from one interface between a first layer and a second layer to an opposing interface between the second layer and a third layer. Dopant concentration may refer to the density of impurities in a layer that are not inherently intrinsic or ordinarily found in that layer material. For example, a silicon-based layer may have dopants or impurities introduced into the layer during deposition that may influence the electrical properties of the silicon layer by altering the electron and hole carrier concentrations of the silicon layer. Such doped layers might consist of an silicon-based alloy, preferably containing Oxygen or Carbon to improve their optical transparency. P-type dopants may increase the hole concentration and may include elements such as Boron. N-type dopants increase the electron concentration and may include elements such as Phosphorus. Hydrogen content might be evaluated by e.g. Fourier Transform spectroscopy or by its indirect effect on the optical gap. Crystallinity may indicate the arrangement of the molecular structure of the silicon layer regarding the ordering of the silicon structure. A film is said to have a higher crystallinity when the arrangement of the silicon is ordered or consistent over distance. This higher crystallinity silicon layers may be referred to as microcrystalline or nanocrystalline. In contrast, silicon layer with a high degree of randomness are likely to be referred to as amorphous and exhibit different electrical properties than higher crystallinity silicon. Hence, the varying types of silicon layers may be used to optimize the performance of the solar cells 200, 204.

The silicon layer characteristics may influence the conversion efficiency of the solar cell device 100. Efficiency may also be improved by stacking two or more solar cells within the same solar cell device 100. For example, in one specific embodiment, the solar cell device 100 may include a first solar cell 102 and a second solar cell 104 that may be integrated with a glass substrate 106, a first transparent conductive oxide layer 108, a reflector layer 110, and a second transparent conductive oxide 112. The solar radiation may be emitted through the glass substrate 106 and the first transparent conductive oxide layer 108 into the first solar cell 102 and the second solar cell 104.

In this embodiment, the solar cells 102, 104 may be in a “p-i-n” configuration that is indicative of the doping configuration of the silicon layers. The doping configuration reflects the addition of atoms that may alter the electron and hole carrier concentrations within the silicon layer. The “p” refers to p-type dopants that increase the hole concentration and may include, but are not limited to, Boron, Gallium, or a combination thereof. The “i” refers to intrinsic doping level that means the silicon layer does not have any significant dopant species. In general, a silicon layer may be considered intrinsic when the doping levels are lower than the surrounding “n” and “p” silicon layers. The “n” refers to n-type dopants that increase the electron concentration and may include, but are not limited to, Phosphorus, Arsenic, or a combination thereof.

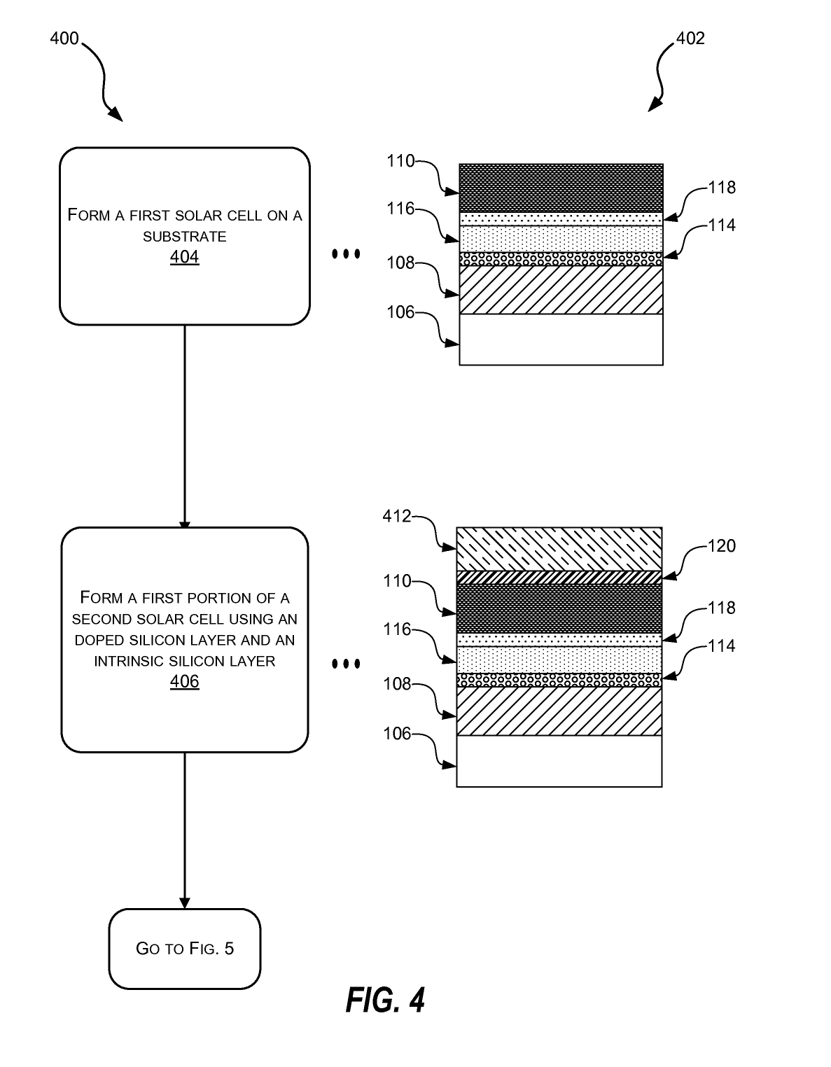

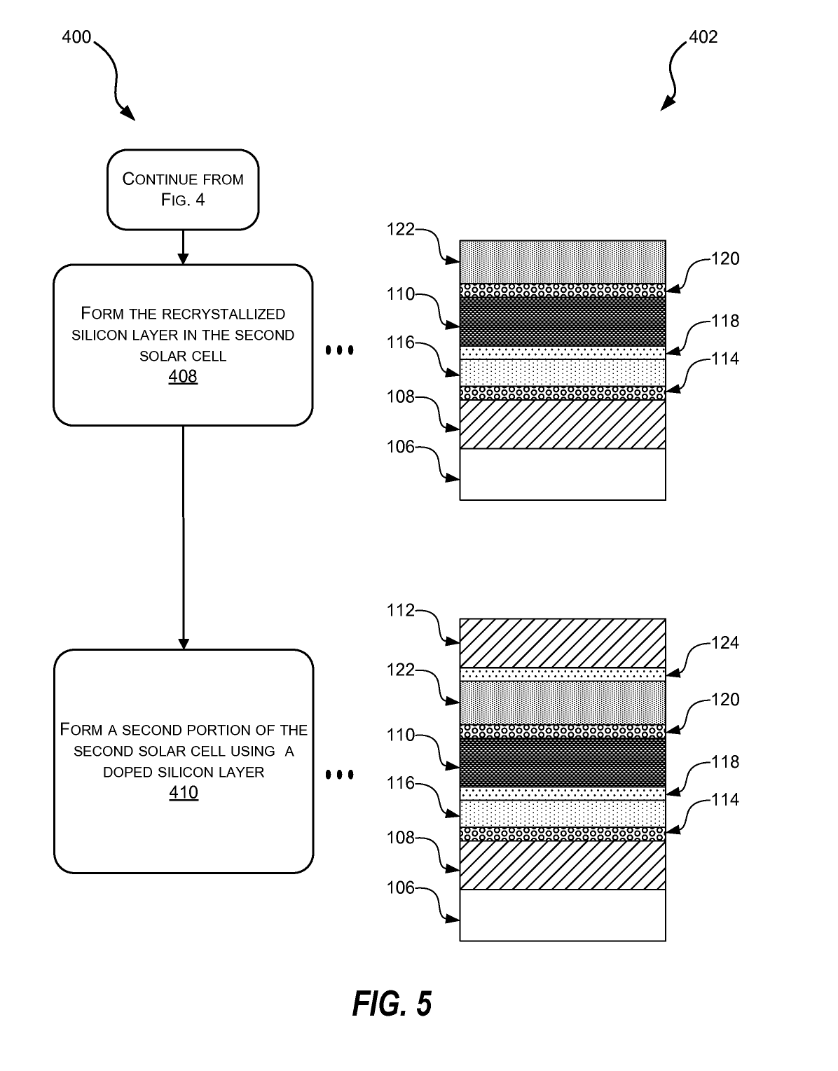

The first solar cell 102 may be used to convert solar radiation into electricity or current flow that may be used to power other electrical devices. The first solar cell 102 may include a first p-layer 114, a second i-layer 116, and a first n-layer 118. The second solar cell 104 may include the second p-layer 120, the second i-layer 122, and a second n-layer 124. Generally, the solar cells 102, 104 may be formed by depositing layers of silicon with different dopant concentrations. The silicon layers may also vary based on their crystallinity, such that the silicon layers may be microcrystalline or amorphous. Crystallinity may be classified based, at least in part, on the structure of the silicon, or more particularly, the degree of order in the arrangement of the silicon molecules in the silicon layer. The higher degree of order may classify the silicon layer as microcrystalline, whereas a lower degree of order may classify the silicon layer as amorphous. The crystallinity may be based, at least in part on, the process conditions during deposition. In one specific example, microcrystalline silicon may be grown at higher pressures and higher power densities than amorphous silicon, such that the process time for microcrystalline silicon takes longer to deposit. Longer deposition times increase the cost of manufacturing. However, amorphous silicon may be recrystallized to microcrystalline silicon by exposing the silicon layer to high temperature or other energy, such as a laser. In this way, a relatively fast deposited amorphous silicon layer may be converted to a microcrystalline layer and may result in lower manufacturing costs of the solar device 100. In one embodiment, the second i-layer 122 may be deposited as amorphous silicon and then recrystallized to a microcrystalline layer. The methods for recrystallization will be described in the description of FIGS. 4-7.

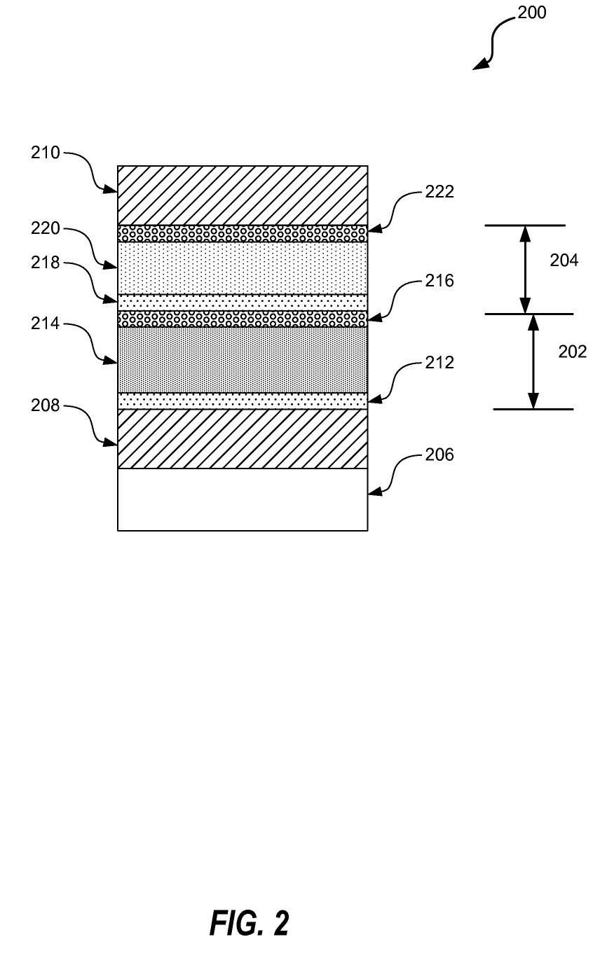

FIG. 2 illustrates a diagram of a multi-junction n-i-p solar device 200 comprising a first solar cell 202 and a second solar cell 204. The n-i-p solar device 200 may include a glass substrate 206, a first transparent conductive oxide layer 208, and a second transparent conductive oxide layer 210. The n-i-p solar device 200 may designate the order of the silicon layers within the first solar cell 202 and the second solar cell 204. For example, in contrast to the p-i-n device described in FIG. 1, the location of the n-layers and p-layers are switched. As shown in FIG. 2, the first n-layer 212 is deposited on top of the first transparent conductive oxide layer 208 followed by the first i-layer 214 and the first p-layer 216. In this embodiment, the first i-layer 214 may be the recrystallized silicon layer for the n-i-p solar device 200. The second solar cell 204 may be deposited over the first solar cell 202. The second solar cell 204 may include a second n-layer 218, a second i-layer 220, and a second p-layer 222.

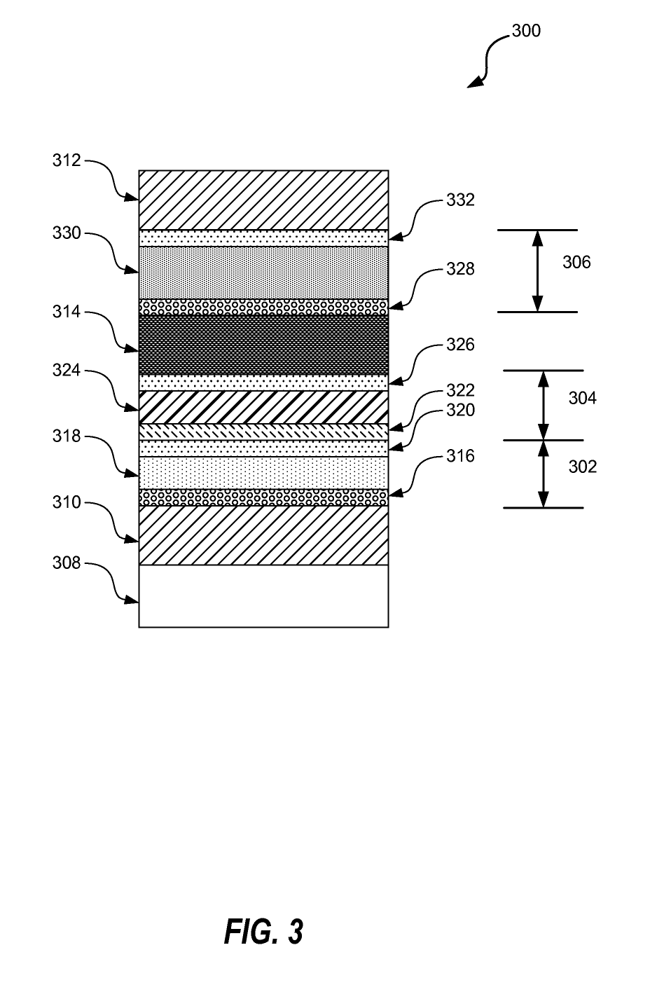

FIG. 3 illustrates a diagram of a triple p-i-n solar device 300 comprising a a first solar cell 302, a second solar cell 304, and a third solar cell 306 that includes a recrystallized silicon layer 330. The solar device 300 may also include a glass layer 308, a first transparent conductive oxide layer 310, and a second transparent conductive oxide layer 312. However, the FIG. 3 embodiment is only one specific embodiment and other layers may be included or one or more of the shown layers maybe omitted.

The first solar cell 302 may include three or more silicon layers to form the p-i-n configuration. In one specific embodiment, the first solar cell 302 may include three silicon layers, such as a first p-layer 316, a first i-layer 318, and a first n-layer 320. The thickness of each i-layer may vary between 80 nm and 200 nm and they may be microcrystalline or amorphous silicon layers.

The second solar cell 304 may be disposed on the first solar cell 302 or disposed on an intermediate layer disposed between the first solar cell 302 and the second solar cell 304. In one specific embodiment, the second solar cell 304 may include three silicon layers, such as a second p-layer 322, a second i-layer 324, and a second n-layer 326. The thickness of the i-layer may vary between 200 nm and 1000 nm and they may be microcrystalline or amorphous silicon layers.

The third solar cell 306 may be disposed on a reflector layer 314 or the second solar cell 304. In one specific embodiment, the third solar cell 304 may include three silicon layers, such as a third p-layer 328, a third i-layer or recrystallization layer 330, and a third n-layer 332. The thickness of each layer may vary between 500 nm and 10 micrometers and they may be deposited as amorphous silicon. The recrystallization layer 330 may be formed as microcrystalline following a post deposition heat treatment or laser treatment that will be discussed in the description of FIGS. 4-7.

FIGS. 4 & 5 illustrate a method 400 for generating a multi-junction p-i-n solar cell and corresponding FIGS. 402 for acts or steps described in the method 400. In one embodiment, the multi-junction p-i-n solar cell may be the multi-junction p-i-n solar device 100, as shown in FIG. 1. However, in other embodiments, the multi-junction p-i-n solar cell may include additional or different layers and may also omit one or more layers to form a functional solar conversion device.

At block 404, the first solar cell 102 may be formed on a substrate 106 and a first transparent conductive oxide 108. The first solar cell 102 may include a first p-layer 114, a first i-layer 116, and a first n-layer 118 to form the first junction of the multi-junction p-i-n solar cell. The thickness and composition of the first solar cell 102 is further described in the description of FIG. 1. The first solar cell 102 may be capped with a reflector layer 110 comprising a transparent layer such as conductive oxide that has a thickness of at least 0.1 μm.

At block 406, a first portion of the second solar cell 104 may be formed on top of the first solar cell 102 or the reflector layer 110. The second p-layer 120 and the intrinsic layer 412 may be deposited as amorphous silicon. The second p-layer 120 and the intrinsic layer 412 may be deposited sequentially in the same process chamber by varying the process conditions (e.g., temperature, dopant gas flow, alloying element etc.). For example, the second p-layer 120 may be deposited under a first set of process conditions that may be transitioned to a second set of process conditions that form the intrinsic layer 412. In one instance, the first process conditions may include a p-type dopant gas flow and the second set of process conditions may not include the p-type dopant gas flow or any other type of dopant gas flow.

The second set of process conditions may include temperature and pressure settings that may enable the deposition of amorphous silicon. In order to favor recrystallization, high deposition rate of amorphous with a total atomic Hydrogen content lower that 10% is preferred. As noted above in the descriptions of FIG. 1, amorphous silicon may have a relatively low level of crystallinity in the silicon layer and may be referred to as non-crystalline silicon. Additionally, the second i-layer 412 may have a second atomic hydrogen concentration between 10% and 25%. In one embodiment, the second i-layer 412 may comprise a thickness between 0.5 μm and 10 μm.

At block 408, the recrystallized silicon layer 122 may be formed by treating the second i-layer 412, such that the recrystallized silicon layer 122 comprises a third hydrogen concentration that is lower than the first hydrogen concentration or the second hydrogen concentration. Additionally, the crystallinity of the recrystallized silicon layer 122 may be higher than the second i-layer 412. For example, the recrystallized silicon layer 122 may be characterized as microcrystalline rather than as amorphous.

The recrystallization process may occur by imparting energy to the second i-layer 412 such that the molecular structure becomes more ordered or microcrystalline-like. Energy may be imparted by exposing the second i-layer 412 to higher temperatures or to targeted amounts of energy (e.g., lasers, electron beam). In one embodiment, the process temperature may be between 25 degrees C. and 200 degrees C. In another embodiment, a laser comprising an energy density between 50 mJ/cm² and 800 mJ/cm² and a pulsing frequency of 10 kHz may be applied to the second i-layer 408. In yet another embodiment, the second i-layer 408 may be exposed to a temperature between 150 degrees C. and 200 degrees C. while applying a laser with an energy density between 20 kW/cm² to 30 kW/cm². In certain instances, the wavelength of the laser may be between 450 nm and 570 nm; alternatively continuous wave laser at 808 nm with exposure times on 100 microseconds to 20 miliseconds can be used. When needed, a post-hydrogenation plasma treatment is performed on the laser-processed layer before the deposition of the n-layer.

At block 410, the second portion of the second solar cell 104 may be formed on the recrystallized silicon layer 122. This may include the deposition of the second n-type layer 124 and the second transparent conductive oxide layer 112, as shown in FIG. 5.

In another embodiment, a third solar cell (not shown) may be disposed between the first solar cell 102 and the second solar cell 104. An example of the three solar cell embodiment is shown in FIG. 3.

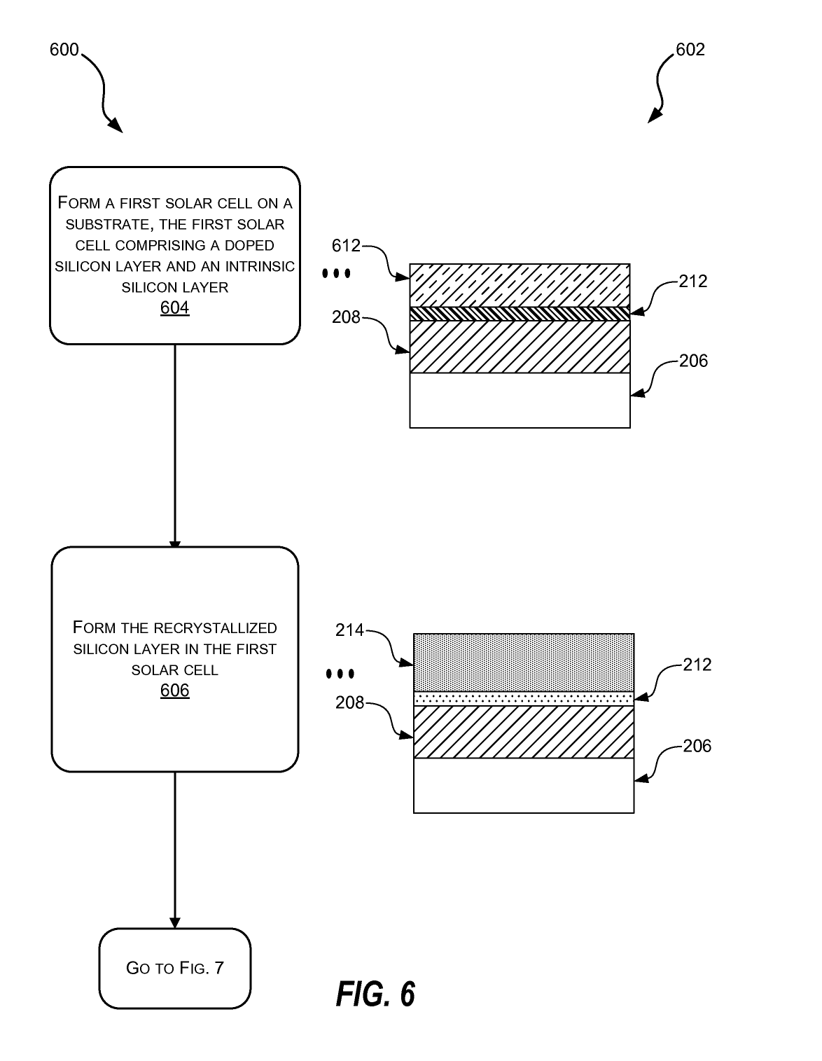

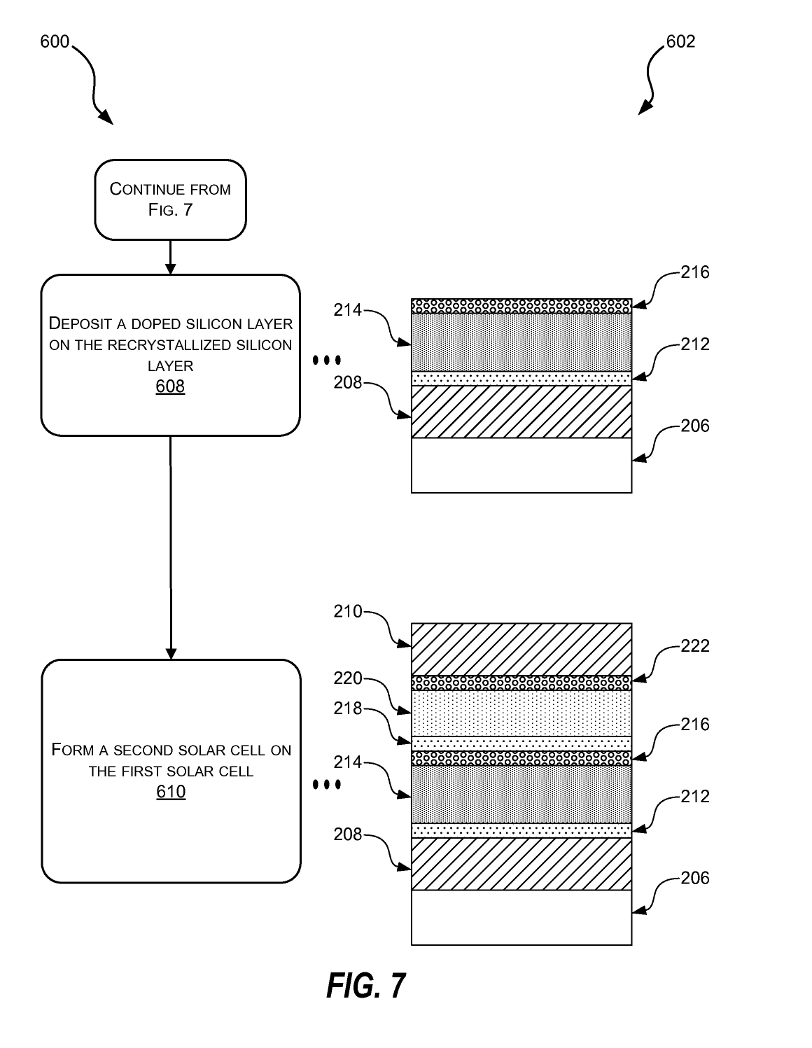

FIGS. 6 & 7 illustrate a method 600 for generating a multi-junction n-i-p solar cell and corresponding FIGS. 602 for acts or steps described in the method 600. In one embodiment, the multi-junction p-i-n solar cell may be the multi-junction n-i-p solar device 200, as shown in FIG. 2. However, in other embodiments, the multi-junction n-i-p solar cell may include additional or different layers and may also omit one or more layers to form a functional solar conversion device.

At block 604, a substrate 206 may include one or more film layers deposited on a surface with each layer overlying the preceding layer. For example, a first transparent conductive oxide 208 may be deposited on the surface of the substrate 206. A first n-type layer 212 may be deposited on the first conductive oxide layer 208. Next, an amorphous i-layer 612 may be deposited on the first n-type layer 212. The amorphous i-layer 612 may comprise a first crystallinity that is less than typical crystallinity values for microcrystalline silicon layer. In other words, the amorphous layers may not include a high range of order to the molecular structure and have a higher degree of randomness than a microcrystalline layer.

At block 606, a laser may be applied to the amorphous i-layer 612 to initiate a recrystallization process that improves the long range order of the amorphous silicon molecular structure. The energy density of the laser may comprise at least 200 mJ/cm². The laser may also be pulsed at a frequency of 10 kHz.

At block 608, after a surface hydrogenation step such as a Hydrogen plasma, a p-type doped silicon layer 216 may be deposited on the recrystallized intrinsic silicon layer 214 to complete the formation of the first solar cell 202 of the solar device 200.

At block 610, the second solar cell 204 may be formed adjacent to the p-type doped silicon layer 216. The second solar cell may include, but is not limited to, an n-type doped silicon layer 216, an intrinsic silicon layer 220, and a p-type doped silicon layer 222. The second solar cell 204 may also have a transparent conductive oxide layer 210 deposited on the surface of the p-type doped silicon layer 222.

Although only certain embodiments of this application have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method for building a solar cell device, comprising:
forming a first solar cell on a substrate; and
forming a second solar cell proximate to the first solar cell, the second solar cell comprising a recrystallized silicon layer.

2. The method of claim 1, wherein the forming of the second solar cell comprises:
depositing a p-type doped silicon layer;
depositing an intrinsic silicon layer on the p-type doped silicon layer, the intrinsic silicon layer comprising a first hydrogen concentration;
forming the recrystallized silicon layer by treating the intrinsic silicon layer, such that the recrystallized silicon layer comprises a second hydrogen concentration that is smaller than the first hydrogen concentration; and
depositing an n-type doped silicon layer on the recrystallized silicon layer.

3. The method of claim 2, wherein the treating comprises applying a laser or an e-beam to the intrinsic silicon layer.

4. The method of claim 3, wherein the laser comprises an energy density between 50 mJ/cm² and 800 mJ/cm² and a pulsing frequency of 10 kHz.

5. The method of claim 3, further comprising heating the substrate between 20 C and 250 C when applying the laser at an energy density between 20 kW/cm² to 30 kW/cm².

6. The method of claim 3, wherein the laser comprises a wavelength between 450 nm and 570 nm.

7. The method of claim 1, further comprising depositing a transparent reflective layer on the first solar cell prior to forming the second solar cell, the reflective layer comprising a transparent conductive oxide and a thickness of at least 0.5 μm.

8. The method of claim 1, wherein the intrinsic silicon layer comprises a thickness between 0.5 μm and 10 μm.

9. The method of claim 2, wherein the p-type doped silicon layer comprises hydrogenated amorphous silicon and the recrystallized silicon layer comprises microcrystalline silicon.

10. The method of claim 1, further comprising forming a third solar cell disposed between the first solar cell and the second solar cell.

11. The method of claim 1, wherein the first solar cell comprises p-typed doped silicon layer, an intrinsic silicon layer, and an n-type doped silicon layer.

12. A method for building a solar cell device, comprising:
depositing a transparent conductive oxide on a substrate;
depositing an n-type doped silicon layer on the transparent conductive oxide;
depositing an intrinsic silicon layer on the n-type doped silicon layer;
applying an energy density of at least 50 mJ/cm² to the intrinsic silicon layer;
depositing a p-type doped silicon layer on the intrinsic silicon layer; and
forming a solar cell adjacent to the p-type doped silicon layer.

13. The method of claim 1, wherein the solar cell comprises one or more silicon layers.

14. The method of claim 2, wherein the applying the energy comprises using a laser that is pulsed at a frequency of 10 kHz.

15. A method for building a solar cell device, comprising:
forming a first solar cell on a substrate, the first solar cell comprising three or more amorphous silicon layers;
forming a second solar cell on the first solar cell, the second solar cell comprising an amorphous silicon layer and two microcrystalline silicon layers; and
forming a third solar cell proximate to the first solar cell, the second solar cell comprising a recrystallized silicon layer.

16. The method of claim 1, wherein the forming of the third solar cell comprises:
depositing a p-type doped amorphous silicon layer;
depositing an intrinsic amorphous silicon layer on the p-type doped silicon layer;
forming the recrystallized silicon layer by treating the intrinsic amorphous silicon layer to decrease hydrogen content and increase crystallinity of the intrinsic amorphous silicon layer; and
depositing an n-type doped silicon layer on the recrystallized silicon layer.

17. The method of claim 2, wherein the treating comprises applying a laser to the intrinsic silicon layer.

18. The method of claim 3, wherein the laser comprises an energy density between 50 mJ/cm² and 800 mJ/cm² and a pulsing frequency of 10 kHz.

19. The method of claim 3, further comprising heating the substrate between 20 C and 250 C when applying the laser at an energy density between 20 kW/cm² to 30 kW/cm².

20. The method of claim 3, wherein the laser comprises a wavelength between 450 nm and 570 nm.
